(19) United States
(12) Patent Application Publication
(10) Pub. No.: US 2026/0265901 A1
(43) Pub. Date: Sep. 10, 2026

(54) METHOD FOR MANUFACTURING COMPOSITE HEAT DISSIPATION STRUCTURE

(71) Applicant: CMTEK Co., Ltd., Hsinchu County (TW)

(72) Inventors: CHIN-JUI LIANG, Hsinchu City (TW); CHIA-CHIANG YANG, Hsinchu City (TW); Yu-Wei Tsai, Taoyuan City (TW); LI-HSIANG CHEN, Hsinchu County (TW); CHIN-PING LIN, Hsinchu City (TW)

(21) Appl. No.: 19/286,180

(22) Filed: Jul. 30, 2025

(30) Foreign Application Priority Data
Mar. 5, 2025 (TW) 114108028

(51) Int. Cl. C23C 14/18; C23C 14/24

(52) U.S. Cl. CPC C23C 14/18; C23C 14/24

(57) ABSTRACT

A method for manufacturing a composite heat dissipation structure. A rigid porous carrier made of a hard material including silicon carbide is first provided. Then, a metal vapor infiltration treatment is performed on the rigid porous carrier. The metal vapor infiltration treatment includes vaporizing a melt of a high-thermal-conductivity metal material to produce a vapor mixture that penetrates into pores of the rigid porous carrier.

### CROSS-REFERENCE TO RELATED PATENT APPLICATION

This application claims the benefit of priority to Taiwan Patent Application No. 114108028, filed on Mar. 5, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method for manufacturing a heat dissipation structure, and more particularly to a method for manufacturing a composite heat dissipation structure.

### BACKGROUND OF THE DISCLOSURE

Electronic products are constantly being improved and updated. In order to meet the requirements of high integration, high transmission, high speed, and high efficiency, electronic products also have higher requirements for heat dissipation efficiency, in addition to basic functions. Commonly used cooling solutions, such as installing cooling fans or metal heat sinks, are insufficient to cope with the cooling problems that can occur in servers and high-power products.

Silicon carbide has excellent characteristics such as high thermal conductivity, cold and hot shock resistance, acid and alkali resistance, lightness, and thinness. Silicon carbide-based heat spreaders have become one of the key components in the development of thermal management construction technology. However, the performance of such heat spreaders also depends on characteristics of the microstructure of silicon carbide after molding, such as the pore size, the porosity, the pore distribution, and the pore connectivity thereof. Yet, the conventional methods for manufacturing such heat spreaders generally have room for improvement in terms of process stability and product yield. For example, during the ceramic forming step, it is difficult to control the microstructure of the ceramic, resulting in poor process stability. As another example, during the impregnation step, the molten liquid containing metal cannot easily penetrate into the ceramic pores, resulting in a low yield of finished products.

### SUMMARY OF THE DISCLOSURE

In response to the above-referenced technical inadequacies, the present disclosure provides a method for manufacturing a composite heat dissipation structure. The present disclosure can ensure that internal pores of a rigid porous carrier are fully filled with a high-thermal-conductivity metal material and that the distribution of the high-thermal-conductivity metal material is continuous and uniform, thereby improving thermal performance, by virtue of adopting gas-phase metal infiltration in place of liquid-phase metal infiltration.

In order to solve the above-mentioned problems, one of the technical aspects adopted by the present disclosure is to provide a method for manufacturing a composite heat dissipation structure, which includes: providing a rigid porous carrier that is made of a hard material including silicon carbide; and performing a metal vapor infiltration treatment on the rigid porous carrier. The metal vapor infiltration treatment includes vaporizing a melt of a high-thermal-conductivity metal material to produce a vapor mixture that penetrates into pores of the rigid porous carrier.

In one of the possible or preferred embodiments, in the metal vapor infiltration treatment, the vapor mixture of the high-thermal-conductivity metal material is formed into a metal surface layer coated on an outside of the rigid porous carrier.

In one of the possible or preferred embodiments, the vapor mixture includes a metal atomic gas, a metal molecular gas, and/or a plasma gas derived from the high-thermal-conductivity metal material.

In one of the possible or preferred embodiments, the high-thermal-conductivity metal material is metallic aluminum, metallic copper, an aluminum-based alloy, or a copper-based alloy.

In one of the possible or preferred embodiments, the high-thermal-conductivity metal material is an aluminum-copper alloy having a copper content from 20% to 80%.

In one of the possible or preferred embodiments, the high-thermal-conductivity metal material is an aluminum-copper-silver alloy having a copper content from 20% to 80% and a silver content from 5% to 30%.

In one of the possible or preferred embodiments, the metal vapor infiltration treatment is performed in a vacuum environment with a pressure from 0.01 torr to 10 torr and a temperature from 500° C. to 1000° C.

In one of the possible or preferred embodiments, the step of providing the rigid porous carrier includes performing a sintering treatment on the hard material, and a porosity of the rigid porous carrier ranges from 20% to 70%.

In one of the possible or preferred embodiments, the step of providing the rigid porous carrier includes: using a binder to form the hard material into a preform by pressing; and performing a heat treatment to remove the binder from an interior of the preform.

In one of the possible or preferred embodiments, the hard material includes at least one of single-crystal silicon, diamond, diamond-like carbon, boron nitride, and graphene.

In conclusion, the method for manufacturing a composite heat dissipation structure provided by the present disclosure can have the advantages of good process stability, a short cycle time, convenience in operation and control, low costs, and high product quality, by virtue of “performing a metal vapor infiltration treatment on the rigid porous carrier” and “the metal vapor infiltration treatment including vaporizing a melt of a high-thermal-conductivity metal material to produce a vapor mixture that penetrates into pores of the rigid porous carrier.” Furthermore, the composite heat dissipation structure exhibits excellent thermal and mechanical properties, and when applied in advanced packaging, it can avoid issues including a thermal expansion coefficient (CTE) mismatch, warpage, delamination, peeling, and cracking, thereby improving process yield and reducing costs.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for manufacturing a composite heat dissipation structure of the present disclosure;

FIG. 2 is a schematic view of a rigid porous carrier of the composite heat dissipation structure of the present disclosure;

FIG. 3 is a schematic enlarged view of part III of FIG. 2, showing small-size, mid-size, and large-size particles of a hard material that are bonded together by sintering according to a first embodiment of the present disclosure;

FIG. 4 is a schematic enlarged view of part III of FIG. 2, showing the small-size, mid-size, and large-size particles of the hard material that are bonded together by a binder according to a second embodiment of the present disclosure; and

FIG. 5 is a schematic view of the composite heat dissipation structure of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

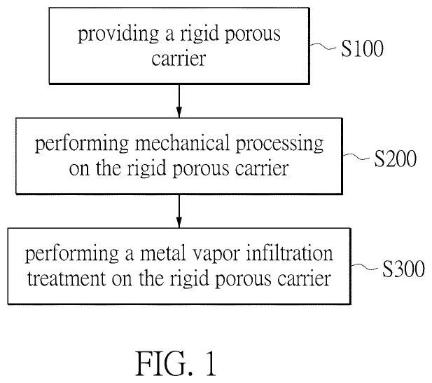

Referring to FIG. 1, a method for manufacturing a composite heat dissipation structure according to a first embodiment of the present disclosure is shown. As shown in FIG. 1, the method for manufacturing the composite heat dissipation structure of the present disclosure includes: step S100, providing a rigid porous carrier; and step S300, performing a metal vapor infiltration treatment on the rigid porous carrier.

In the present disclosure, a high-thermal-conductivity metal material is introduced into a rigid porous carrier by using a metal vapor infiltration reaction, in which the extent of the metal vapor infiltration reaction can be controlled by controlling conditions such as a vacuum level, a reaction temperature, and a reaction pressure, thereby achieving unexpected results. Specifically, internal pores of the rigid porous carrier are fully filled with the high-thermal-conductivity metal material, and the high-thermal-conductivity metal material can be uniformly distributed on an external surface of the rigid porous carrier. Therefore, a resulting composite heat dissipation structure can offer superior quality and better performance, and is thus widely applicable in many fields, such as semiconductor, aerospace, and military industry.

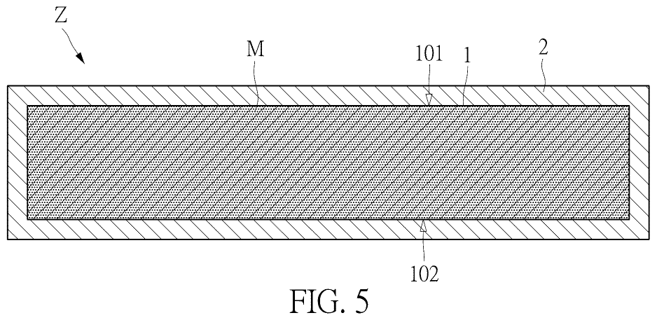

Reference is made to FIG. 5, illustrating that after the above steps are completed, a composite heat dissipation structure Z can be obtained, which includes a rigid porous carrier 1 and a metal surface layer 2. The rigid porous carrier 1 is made of a hard material including silicon carbide. The metal surface layer 2 is coated on an external surface of the rigid porous carrier 1, such as an upper surface 101 and/or a lower surface 102. The metal surface layer 2 is formed by performing a metal vapor infiltration treatment on the rigid porous carrier 1. The metal vapor infiltration treatment includes vaporizing a melt of a high-thermal-conductivity metal material M to produce a vapor mixture that is deposited on an external surface of the rigid porous carrier 1 and filled into pores of the rigid porous carrier 1. Therefore, the composite heat dissipation structure Z has many excellent properties, including high rigidity, high thermal conductivity, high strength, and good thermal dimensional stability, and is highly suitable for application in advanced package structures of one or more semiconductor dies (semiconductor chips).

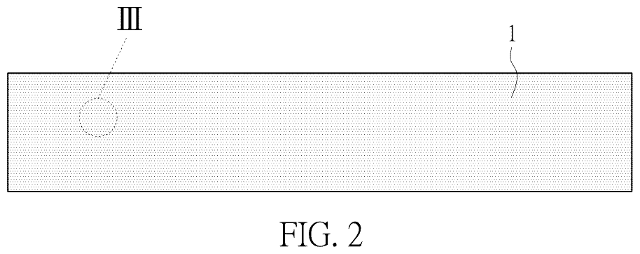

The high-thermal-conductivity metal material M suitable for use in the present disclosure includes, but is not limited to, metallic aluminum, metallic copper, an aluminum-based alloy, and a copper-based alloy. Referring to FIG. 2, FIG. 3, and FIG. 5, each step of the method for manufacturing the composite heat dissipation structure of the present disclosure will be described in detail below.

In step S100, the rigid porous carrier 1 is made of a hard material including silicon carbide, thereby exhibiting characteristics such as high porosity, high rigidity, high thermal stability, and a low thermal expansion coefficient. Accordingly, the rigid porous carrier 1 is suitable for carrying a high-thermal-conductivity metal material so as to meet practical heat dissipation requirements. Specifically, the hard material can be formed into a preform having a desired shape by pressing (e.g., press molding), and the preform is then subjected to a sintering treatment that is performed under normal pressure (1 atm) or a vacuum or special atmospheric condition at a sintering temperature from 800° C. to 1500° C., but the present disclosure is not limited thereto.

In the present disclosure, a porosity of the rigid porous carrier 1 ranges from 20% to 70%, i.e., a pore volume in the rigid porous carrier 1 accounts for 20% to 70% of a total volume of the rigid porous carrier 1. Depending on mechanical and thermal conductivity requirements, the hard material can further include at least one of single-crystal silicon, diamond, diamond-like carbon, boron nitride, and graphene.

More specifically, the hard material can be present in the form of a powder that includes small-size particles 13, mid-size particles 12, and large-size particles 11. A particle size ratio of the small-size particles 13, the mid-size particles 12, and the large-size particles 11 is 1:2-2.5:3-20. The small-size particles 13, the mid-size particles 12, and the large-size particles 11 are bonded together by sintering to form an integrated structure such as a ring-shaped or plate-shaped structure.

In practice, a particle size of the small-size particles 13 ranges from 0.1 μm to 5 μm, a particle size of the mid-size particles 12 ranges from 2 μm to 10 μm, and a particle size of the large-size particles 13 ranges from 10 μm to 100 μm. It should be noted that as a dimension (e.g., a thickness) of the rigid porous carrier 1 changes, the particle sizes of the small-size particles 13, the mid-size particles 12, and the large-size particles 11 proportionally increase or decrease according to the aforementioned ratio. Preferably, a weight ratio of the small-size particles 13, the mid-size particles 12, and the large-size particles 11 is 1:3:4, based on a total weight of the rigid porous carrier 1.

In step S300, the rigid porous carrier 1 can be placed in a vacuumed reaction chamber, and the high-thermal-conductivity metal material can be melted by heating and introduced into the reaction chamber. Afterwards, a melt of the high-thermal-conductivity metal material is vaporized under controlled conditions to produce a vapor mixture that contains a gaseous metal and fills the reaction chamber. Therefore, the vapor mixture can infiltrate the rigid porous carrier 1 from different directions to fill into its pores, and transforms into a solid-phase metal in the pores of the rigid porous carrier 1. Furthermore, the vapor mixture can be deposited and adhered on the external surface of the rigid porous carrier 1, so as to form a metal surface layer 2 coated on an outside of the rigid porous carrier 1.

It is worth mentioning that, in the metal vapor infiltration treatment, the concentration of the vapor mixture can be controlled by controlling process parameters such as a vacuum level, a temperature, and a pressure, thereby allowing convenient control of a rate and a depth of the vapor mixture infiltrating into the rigid porous carrier 1. Accordingly, the limitations inherent in liquid-phase metal infiltration can be overcome.

In the present disclosure, the high-thermal-conductivity metal material infiltrates the rigid porous carrier 1 in the form of a metal vapor, in which the concentration of the metal vapor can meet the requirements of a vapor-phase infiltration reaction by controlling a temperature and a pressure of a vacuum environment. More specifically, the high-thermal-conductivity metal material is vaporized through the triple point to transform into a vapor mixture, which includes a metal atomic gas, a metal molecular gas, and/or a plasma gas derived from the high-thermal-conductivity metal material.

In practice, the pressure of the vacuum environment ranges from 0.01 torr to 10 torr, and the temperature of the vacuum environment ranges from 500° C. to 1000° C. The high-thermal-conductivity metal material can be an aluminum-copper alloy having a copper content from 20% to 80%. Alternatively, the high-thermal-conductivity metal material can be an aluminum-copper-silver alloy having a copper content from 20% to 80% and a silver content from 5% to 30%. Therefore, temperatures for vapor-phase metal infiltration can be lowered, and the thermal conductivity of a composite material can be increased. However, the above description is for exemplary purposes only, and is not meant to limit the scope of the present disclosure.

The copper content of the aluminum-copper alloy or the aluminum-copper-silver alloy serving as the high-thermal-conductivity metal material can be 20%, 25%, 30%, 35%, 40%, 45%, 50%, 55%, 60%, 65%, 70%, 75%, or 80%. The silver content of the aluminum-copper-silver alloy serving as the high-thermal-conductivity metal material can be 5%, 10%, 15%, 20%, 25%, or 30%.

If necessary, between step S100 and step S300, the method for manufacturing the composite heat dissipation structure of the present disclosure can further include: step S200, performing mechanical processing on the rigid porous carrier 1, so as to make the rigid porous carrier 1 have a desired shape or structure that meets practical requirements. The mechanical processing suitable for use according to the present disclosure can include, but is not limited thereto, cutting, grinding, drilling, and grooving.

After the above steps are completed, a composite heat dissipation structure Z can be obtained, which includes the rigid porous carrier 1 as described above and a metal surface layer 2 coated on an outside of the rigid porous carrier 1.

It should be noted that the composite heat dissipation structure Z exhibits excellent thermal and mechanical properties. The composite heat dissipation structure Z has a heat transfer coefficient of greater than 180 W/mK, and preferably from 250 W/mK to 350 W/mK. The composite heat dissipation structure Z has a thermal expansion coefficient from 6 to 20. Furthermore, the composite heat dissipation structure Z has a stiffness modulus from 300 MPa to 600 MPa.

Reference is made to FIG. 5. In the composite heat dissipation structure Z, the rigid porous carrier 1 and the metal surface layer 2 satisfy a relationship: 2A/T≤50%; where A represents a covering thickness of the metal surface layer 2 on an upper surface 101 or a lower surface 102, and T represents a total thickness of the composite heat dissipation structure Z. In practice, the covering thickness of the metal surface layer 2 on the upper surface 101 or the lower surface 102 can be greater than 5 μm, and preferably from 25 μm to 100 μm.

### Second Embodiment

Referring to FIG. 1, a second embodiment of the present disclosure provides a method for manufacturing a composite heat dissipation structure. Process flow steps in the second embodiment are essentially identical to those in the first embodiment, and the difference is that step S200 does not involve sintering a hard material. Specifically, step S200 includes: using a binder to form the hard material into a preform by pressing (e.g., press molding); and performing a heat treatment to remove the binder from an interior of the preform.

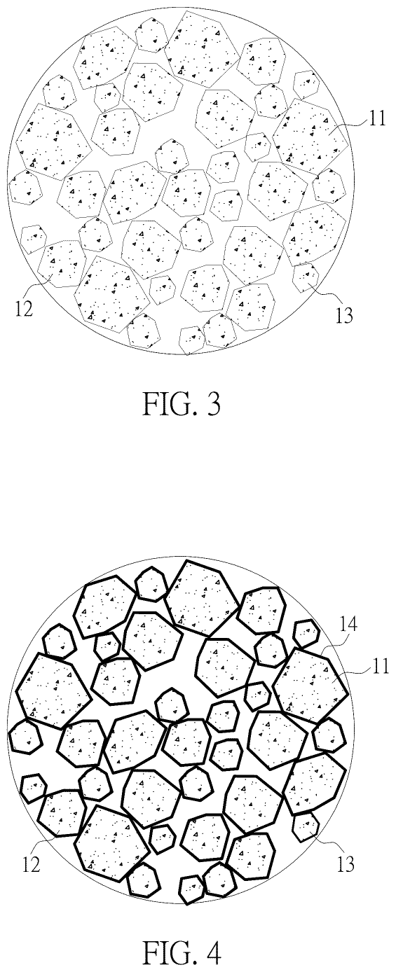

Reference is made to FIG. 4. In the process of pressing the hard material, the small-size particles 13, the mid-size particles 12, and the large-size particles 11 are bonded together by a binder 14 to form an integrated structure such as a block-shaped or sheet-shaped structure. It should be noted that since the pressing with the binder 14 operates at a lower temperature and requires a shorter duration compared to sintering, the rigid porous carrier 1 can be obtained in an energy and time saving manner. After the heat treatment is completed, the rigid porous carrier 1 has a pore or void structure formed after the removal of the binder 14, and “pseudo-adhesion” is established among the small-size particles 13, the mid-size particles 12, and the large-size particles 11.

The related technical features mentioned in the first embodiment are still valid in the present embodiment, and will not be repeated herein for the sake of brevity. Similarly, the related technical features mentioned in the present embodiment can be applied to the first embodiment.

### Beneficial Effects of the Embodiments

In conclusion, the method for manufacturing a composite heat dissipation structure provided by the present disclosure can have the advantages of good process stability, a short cycle time, convenience in operation and control, low costs, and high product quality, by virtue of “performing a metal vapor infiltration treatment on the rigid porous carrier” and “the metal vapor infiltration treatment including vaporizing a melt of a high-thermal-conductivity metal material to produce a vapor mixture that penetrates into pores of the rigid porous carrier.” Furthermore, the composite heat dissipation structure exhibits excellent thermal and mechanical properties, and when applied in advanced packaging, it can avoid issues including a thermal expansion coefficient (CTE) mismatch, warpage, delamination, peeling, and cracking, thereby improving process yield and reducing costs.

The composite heat dissipation structure has many excellent properties, including high rigidity, high thermal conductivity, high strength, and good thermal dimensional stability, and is highly suitable for application in advanced package structures of one or more semiconductor dies (semiconductor chips).

In the metal vapor infiltration treatment, the vapor mixture that includes a metal atomic gas, a metal molecular gas, and/or a plasma gas can infiltrate the rigid porous carrier from different directions. In addition, the concentration of the vapor mixture can be controlled by controlling process parameters such as a vacuum level, a temperature, and a pressure, thereby allowing convenient control of a rate and a depth of the vapor mixture infiltrating into the rigid porous carrier. Therefore, the limitations inherent in liquid-phase metal infiltration can be overcome, and internal pores of the rigid porous carrier can be fully filled with the high-thermal-conductivity metal material.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a composite heat dissipation structure, comprising:
providing a rigid porous carrier, the rigid porous carrier being made of a hard material including silicon carbide; and
performing a metal vapor infiltration treatment on the rigid porous carrier, wherein the metal vapor infiltration treatment includes vaporizing a melt of a high-thermal-conductivity metal material to produce a vapor mixture that penetrates into pores of the rigid porous carrier.

2. The method according to claim 1, wherein, in the metal vapor infiltration treatment, the vapor mixture of the high-thermal-conductivity metal material is formed into a metal surface layer coated on an outside of the rigid porous carrier.

3. The method according to claim 2, wherein the vapor mixture includes a metal atomic gas, a metal molecular gas, and/or a plasma gas derived from the high-thermal-conductivity metal material.

4. The method according to claim 3, wherein the high-thermal-conductivity metal material is metallic aluminum, metallic copper, an aluminum-based alloy, or a copper-based alloy.

5. The method according to claim 4, wherein the high-thermal-conductivity metal material is an aluminum-copper alloy having a copper content from 20% to 80%.

6. The method according to claim 4, wherein the high-thermal-conductivity metal material is an aluminum-copper-silver alloy having a copper content from 20% to 80% and a silver content from 5% to 30%.

7. The method according to claim 3, wherein the metal vapor infiltration treatment is performed in a vacuum environment with a pressure from 0.01 torr to 10 torr and a temperature from 500°C to 1000°C.

8. The method according to claim 1, wherein the process of providing the rigid porous carrier includes performing a sintering treatment on the hard material, and a porosity of the rigid porous carrier ranges from 20% to 70%.

9. The method according to claim 1, wherein the process of providing the rigid porous carrier includes:
using a binder to form the hard material into a preform by pressing; and
performing a heat treatment to remove the binder from an interior of the preform.

10. The method according to claim 1, wherein the hard material includes at least one of single-crystal silicon, diamond, diamond-like carbon, boron nitride, and graphene.
